(19) United States
(12) Patent Application Publication
(10) Pub. No.: US 2026/0247926 A1
(43) Pub. Date: Aug. 20, 2026

(54) BOND PAD CRACK SENSOR INTEGRATION FOR WAFER-TO-WAFER DIE STACK

(71) Applicant: Micron Technology, Inc., Boise, ID (US)

(72) Inventors: Barbara J. Bailey, Kuna, ID (US); Chandrika Mallesh, Boise, ID (US); Qiuying Zhao, San Jose, CA (US); Heather M. Lucero, Boise, ID (US)

(21) Appl. No.: 19/535,573

(22) Filed: Feb. 10, 2026

Related U.S. Application Data
(60) Provisional application No. 63/761,045, filed on Feb. 20, 2025.

(51) Int. Cl. H10P 74/20; H10P 74/00

(52) U.S. Cl. CPC H10P 74/207; H10P 74/273; H10P 74/277

(57) ABSTRACT

Methods, systems, and devices for bond pad crack sensor for wafer-to-wafer die stack are described. In some examples, an integrated assembly may include a memory die coupled with another semiconductor die using a wafer-to-wafer bond interface. The memory die may include a wire bond pad that is along a surface of the memory die that is opposite the wafer-to-wafer bond interface. To accommodate test circuitry that tests a quality and/or a reliability of the wire bond pad, the memory die may use a metallization layer near the surface that is opposite the wafer-to-wafer bond interface to electrically couple the wire bond pad with the test circuitry.

### CROSS REFERENCE

The present Application for Patent claims priority to U.S. Patent Application No. 63/761,045 by Bailey et al., entitled “BOND PAD CRACK SENSOR INTEGRATION FOR WAFER-TO-WAFER DIE STACK,” filed February 20, 2025, which is assigned to the assignee hereof, and which is expressly incorporated by reference in its entirety herein.

### TECHNICAL FIELD

The following relates to one or more systems for memory, including bond pad crack sensor integration for a wafer-to-wafer die stack.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports bond pad crack sensor integration for a wafer-to-wafer die stack in accordance with examples as disclosed herein.

FIG. 2 shows an example of a stacked die assembly that supports bond pad crack sensor integration for a wafer-to-wafer die stack in accordance with examples as disclosed herein.

FIG. 3 shows example manufacturing flows that supports bond pad crack sensor integration for a wafer-to-wafer die stack in accordance with examples as disclosed herein.

FIG. 4 shows a flowchart illustrating a method or methods that support bond pad crack sensor integration for a wafer-to-wafer die stack in accordance with examples as disclosed herein.

### DETAILED DESCRIPTION

A memory die, such as a Not AND flash (NAND) memory die, may include a wire bond pad (e.g., an electrically conductive pad) that connects with a wire bond that electrically couples the memory die with a substrate of a semiconductor package. The memory die may further include test circuitry that is electrically coupled with the wire bond pad to detect cracks and/or predict potential failures in the wire bond pad and/or conductive structures that may be electrically coupled with the wire bond pad. The test circuitry may electrically couple with the wire bond pad using a base metal layer (e.g., an initially deposited layer of a stack of metallization layers, sometime referred to as an “M0” metallization layer) that is below the wire bond pad.

In some cases, the memory die may be part of a stacked die assembly that includes the memory die coupled with another semiconductor die (e.g., a logic die that is coupled with the memory die using wafer-to-wafer stacking). To enable electrical functionality and connect integrated circuitry of the memory die with integrated circuitry of the other semiconductor die, the base metal layer (and associated structures such as a wafer bond pad configured to bond the memory die with the other semiconductor die) may be disposed proximate and/or along an interface (e.g., a wafer-to-wafer bond interface) between the memory die and the other semiconductor die. However, to accommodate a wire bond that electrically couples the memory die with a substrate of a semiconductor package, the wire bond pad may be positioned along a surface of the memory die that is opposite the wafer-to- wafer bond interface and/or the wafer bond pad. Positioning the wire bond pad along the opposite surface may increase a separation distance between the wire bond pad and the base metal layer, and a routing complexities may obviate use of the base metal layer to electrically couple wire bond pad with the test circuitry.

In accordance with examples as described herein, an integrated assembly may include a memory die coupled with another semiconductor die using a wafer-to-wafer bond interface. The memory die may include a wire bond pad that is along a surface of the memory die that is opposite the wafer-to-wafer bond interface. To accommodate test circuitry that tests a quality and/or a reliability of the wire bond pad, the memory die may use a metallization layer near the surface that is opposite the wafer-to-wafer bond interface to electrically couple the wire bond pad with the test circuitry.

In contrast to using a base metal layer proximate the wafer-to-wafer bond interface to electrically couple the wire bond pad with the test circuitry, using the metallization layer to electrically couple the wire bond pad with the test circuitry may reduce routing complexities and improve a performance (e.g., a sensitivity) of the test circuitry. Additionally, or alternatively, the metallization layer may be pre-existing metallization layer of the memory die and not require additional expenses to manufacture the memory die, thereby saving resources (e.g., manufacturing tools, labor, and/or computing resources) utilized to fabricate the memory die.

In addition to applicability in memory systems as described herein, techniques for bond pad crack sensor integration for a wafer-to-wafer die stack may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve a quality and/or a reliability of electronic devices by ensuring functionality of a semiconductor package including the wafer-to-wafer die stack, thereby improving memory access, improving response times, or otherwise improving user experience, among other benefits.

Features of the disclosure are illustrated and described in the context of systems, devices, and circuits. Features of the disclosure are further illustrated and described in the context of system that may include a wafer-to-wafer die stack, a wafer-to-wafer die stack including a bond pad crack sensor that is electrically coupled with a metallization layer proximate a wire bond pad opposite a wafer-to-wafer bond interface, example test flows, and flowcharts.

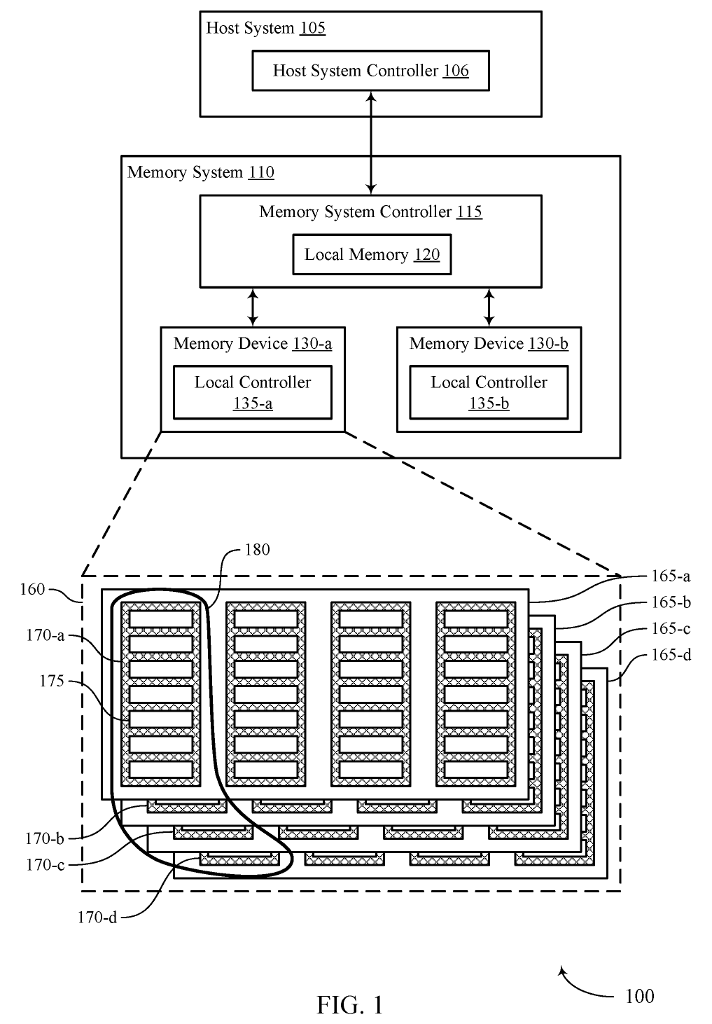

FIG. 1 shows an example of a system 100 that supports bond pad crack sensor for wafer-to-wafer die stack in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a semiconductor wafer (e.g., a silicon die cut from a silicon semiconductor wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

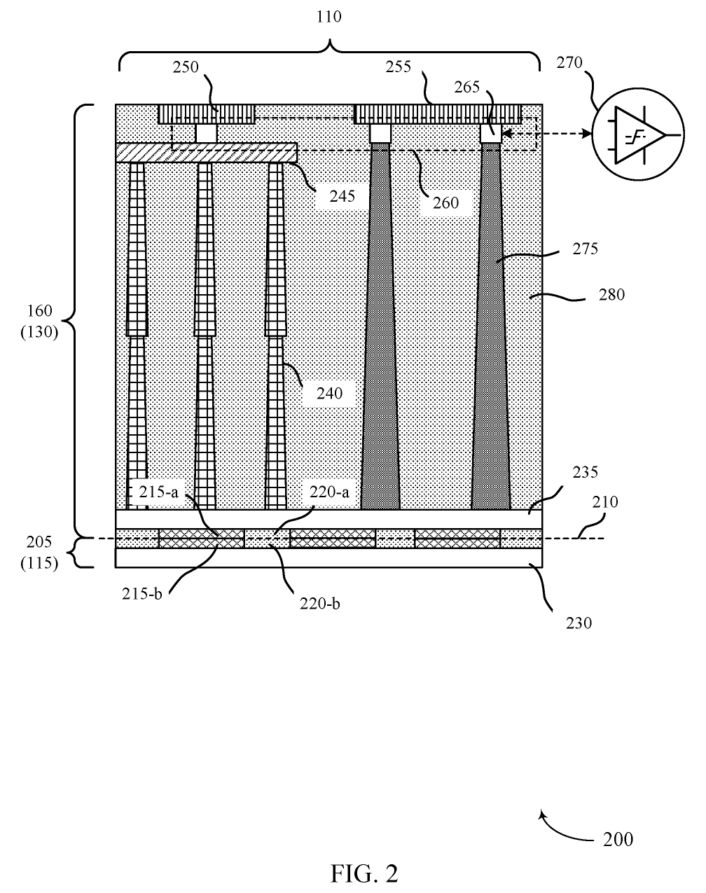

In some examples, a memory system (e.g., the memory system 110, including the memory system controller 115 and the memory device 130) may be an integrated assembly. As described in greater detail in connection with FIGS. 2 through 4, the integrated assembly may be a wafer-to-wafer die stack that includes a memory die (e.g., the die 160 including one or more features of the memory device 130) that is bonded and/or stacked with a logic die (e.g., a logic die including the memory system controller 115). Furthermore, the memory die may include a wire bond pad, where the wire bond pad is positioned on a surface of the memory die that is opposite a bond interface (e.g., a wafer-to-wafer bond interface) between the memory die and the logic die. The memory die may further include a crack-sensing circuitry (e.g., a bond pad crack sensor) coupled with a metallization layer proximate the wire bond pad. The crack-sensing circuitry may be configured to detect defects in the wire bond pad and/or underlying circuitry, either prior to bonding the memory die with the logic die or subsequent to bonding the memory die with the logic die.

FIG. 2 shows an example of an integrated assembly 200 that supports bond pad crack sensor integration for a wafer-to-wafer die stack in accordance with examples as disclosed herein. In FIG. 2, a section view of the integrated assembly 200 (e.g., the memory system 110 of FIG. 1) shows at least a portion of the die 160 (e.g., the die 160, including one or more aspects of the memory device 130 of FIG. 1) bonded with at least a portion of a die 205 (e.g., a logic die, including one or more aspects of the memory system controller 115 of FIG. 1).

As shown in FIG. 2, the die 160 and the die 205 are bonded (e.g., mechanically coupled and/or electrically coupled) along a bond interface 210. In some examples, the bond interface 210 may be a hybrid bond interface that includes a combination of bonding mechanisms, including metal-to-metal bonding and/or dielectric-to-dielectric bonding.

As an example of metal-to-metal bonding, and as shown in FIG. 2, the bond interface 210 may include co-facing surfaces of wafer bond pads 215 (e.g., a surface of the wafer bond pad 215-a on and/or along a surface of the die 160 facing a surface of the wafer bond pad 215-b on and/or along a surface of the die 205). The wafer bond pad 215-a and the wafer bond pad 215-b may each include a metal material (a combination of one or more of gold, aluminum, copper, tin, silver, titanium, and/or another suitable metal material, among other examples). The co-facing surfaces of the wafer bond pad 215-a and the wafer bond pad 215-b may electrically and/or mechanically couple (e.g., bond) with one another through diffusion bonding, grain boundary recrystallization, or eutectic bonding, among other examples.

In some examples, the wafer bond pad 215-a and the wafer bond pad 215-b may be configured to provide an electrical connection between the die 160 and the die 205. Additionally, or alternatively, and in some examples, the wafer bond pad 215-a and the wafer bond pad 215-b may be configured to provide a mechanical connection between the die 160 and the die 205.

As an example of dielectric-to-dielectric bonding, and as shown in FIG. 2, the bond interface 210 may include co-facing surfaces of dielectric regions 220 (e.g., a surface of the dielectric region 220-a on and/or along a surface of the die 160 that faces a surface of the dielectric region 220-b on and/or along a surface of the die 205). The dielectric region 220-a and the dielectric region 220-b may each include a dielectric material (a combination of one or more of silicon dioxide, silicon nitride, and/or another suitable dielectric material, among other examples). The co-facing surfaces of the dielectric region 220-a and the dielectric region 220-b may mechanically couple (e.g., bond) with one another through diffusion bonding, adhesive bonding, or thermocompression bonding, among other examples.

The die 205 may include a metallization layer 230 proximate the bond interface 210. The metallization layer 230 may be a conductive material (e.g., tungsten, aluminum, copper, titanium, titanium nitride, or another suitable conductive material, among other examples). The metallization layer 230 may include traces and/or routing that electrically couple a wafer bond pad (e.g., the wafer bond pad 215-b) with integrated circuitry of the die 205.

The die 160 may include a metallization layer 235 proximate the bond interface 210. The metallization layer 235 may be a conductive material (e.g., tungsten, aluminum, copper, titanium, titanium nitride, or another suitable conductive material, among other examples). In some examples, the metallization layer 235 may be a base metal layer (e.g., an initially deposited metal layer or an “M0” layer) of a metallization stack included in the die 160. In such examples, the metallization layer 235 may, relative to other metallization layers of the metallization stack, be nearest the bond interface 210, a wafer bond pad (e.g., the wafer bond pad 215-a) used to form the bond interface 210 and/or a dielectric region (e.g., the dielectric region 220-a) used to form the bond interface 210. In some examples, the metallization layer 235 may correspond to a bit line that electrically couples with a memory cell of the die 160 and transmits data as part of a write and/or a read operation accessing the memory cell.

As further shown in FIG. 2, the die 160 may include pillar structures 240. Each pillar structure 240 may correspond to a NAND memory cell and may include layers of oxide alternating with layers of nitride and/or polycrystalline silicon. In some examples, a pillar structure 240 may store data using a charge trapping layer or a floating gate. Furthermore, as shown in FIG. 2 and in some examples, the die 160 may include two or more stacked levels of pillar structures 240 (e.g., two or more stacked levels of NAND memory cells).

As further shown in FIG. 2, the die 160 may include a source plate 245. The source plate 245 may be a conductive material (tungsten, copper, polysilicon doped with impurities, or another suitable conductive material, among other examples). In some examples, the source plate 245 may provide a common potential (e.g., ground (GND) or a reference voltage) to the pillar structures 240.

As further shown in FIG. 2, the die 160 may include a peripheral layer 250. The peripheral layer 250 may be a conductive material (aluminum, copper, tungsten, or another suitable conductive material, among other examples). In some examples, the peripheral layer 250 may provide signal routing, power distribution, and/or other electrical connections amongst peripheral circuity of the die 160. Furthermore, and in some examples, the peripheral layer 260 may be positioned on and/or along a surface of the die 160 that is opposite the bond interface 210.

As further shown in FIG. 2, the die 160 may include a wire bond pad 255. The wire bond pad 255 may be a conductive material (aluminum, gold, copper, silver, palladium, or another suitable conductive material, among other examples). In some examples, the wire bond pad 255 may be positioned on and/or along a surface of the die 160 that is opposite the bond interface 210. Furthermore, the wire bond pad 255 may be configured to provide an electrically conductive bond between the die 160 and a connector that is electrically conductive. Such a connector may be a wire bond, a bump, or other suitable electrically conductive structure is part of an electrical coupling between the integrated assembly 200 and a substrate of a semiconductor package that may encapsulate and/or house the integrated assembly.

As further shown in FIG. 2, the die 160 may include a metallization layer 260. The metallization layer 260 may be a conductive material (e.g., tungsten, aluminum, copper, titanium, titanium nitride, or another suitable conductive material, among other examples). In some examples, the metallization layer 260 may be a multi-purpose metallization layer that includes a set of contacts 265 that may be used to electrically couple portions of the peripheral layer 250 and/or the wire bond pad 255 with underlying integrated circuitry of the die 160.

Additionally, or alternatively, the metallization layer 260 may include traces and/or routing (e.g., conductive paths) that electrically couple the wire bond pad 255 with a crack-sensing circuit 270. The crack-sensing circuit 270 (e.g., a test circuit) may include one or more of a comparator, a voltage divider, an operational amplifier, an impedance detector, a bridge circuit, and/or another suitable component suitable for testing the wire bond pad 255 (and/or circuitry electrically coupled with the wire bond pad 255) for cracks and/or other defects.

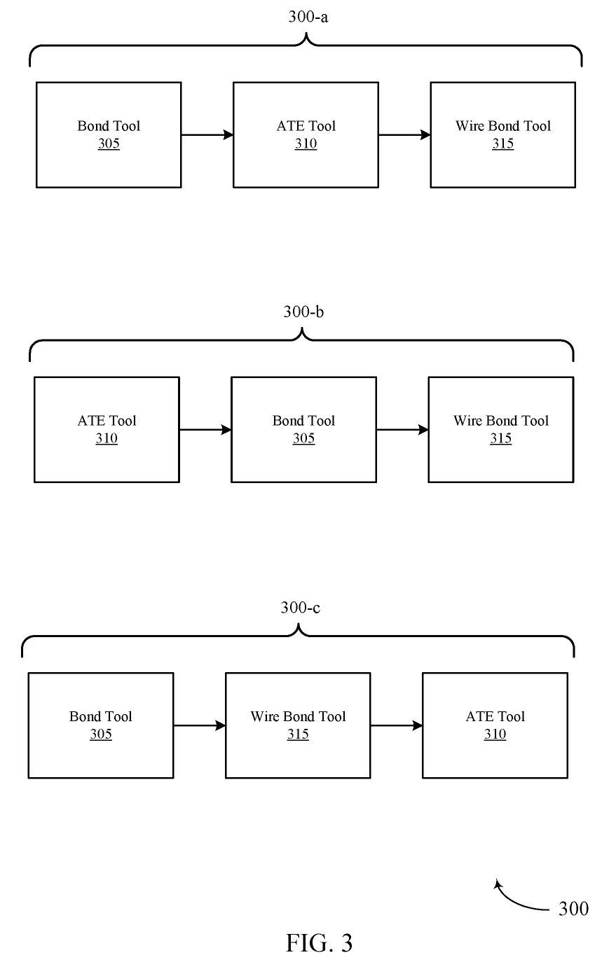

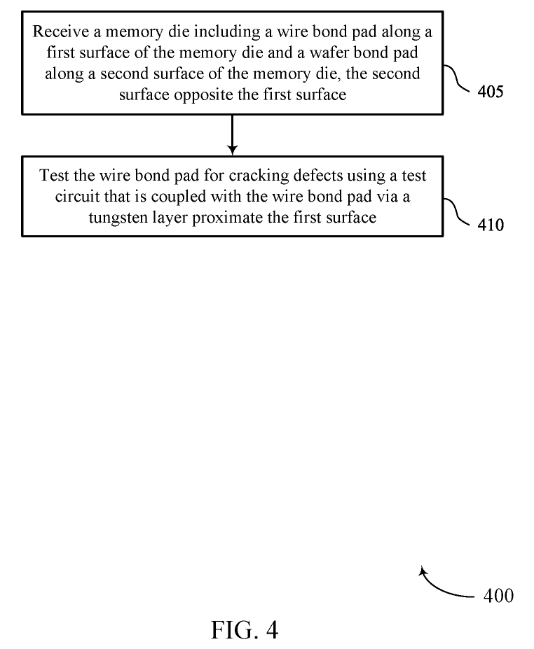

As described in greater detail in connection with FIGS. 3 and 4, and in some examples, a voltage may be applied to the wire bond pad 255. Based on the applied the voltage, and in some cases, the crack-sensing circuit 270 may detect an electrical open condition. The electrical open condition may be indicative of a discontinuity (e.g., a crack or other defect) in the wire bond pad 255 and/or circuitry electrically coupled with the wire bond pad 255.

As shown in FIG. 2, the crack-sensing circuit 270 may be positioned near the wire bond pad 255 and/or the metallization layer 260. In contrast to another configuration in which another crack-sensing circuit may be positioned near the bond interface 210 and/or the metallization layer 235, reduced separation and/or signaling distances associated with the configuration of FIG. 2 (e.g., the crack-sensing circuit 270 electrically coupled with the metallization layer 260) may cause improved performance through improved sensitivity and/or reduced parasitics in the crack-sensing circuit 270, among other examples. In some cases, the crack-sensing circuit 270 may be electrically coupled more directly with metallization layer 260 than metallization layer 235. If the crack-sensing circuit 270 is electrically coupled more directly with the metallization layer 235 it could introduce noise into the crack detection associated with the wire bond pad 255 because the electrical path between the metallization layer 235 and the metallization layer 260 may introduce noise into the signal that is received by the crack-sensing circuit 270.

As further shown n FIG. 2, the die 160 may include a set of contacts 275. Each contact 275 may may be a conductive material (e.g., tungsten, aluminum, copper, titanium, titanium nitride, or another suitable conductive material, among other examples). In some examples, the set of contacts 275 may electrically couple one or more features of the metallization layer 260 with one or more features of the metallization layer 235. Additionally, or alternatively, one or more of the set of contacts 275 may electrically couple with one or more of the set of contacts 265.

As shown in FIG. 2, the pillar structures 240 (e.g., stacked levels of NAND memory cells) may be between the metallization layer 235 and the metallization layer 260. Additionally, or alternatively, the contacts 275 may be between the metallization layer 235 and the metallization layer 260. In some examples, and as shown in FIG. 2, a dielectric fill 280 may surround the pillar structures 240 and/or the contacts 275 to electrically isolate metallization layer 235, the pillar structures 240, the metallization layer 260, and/or the contacts 275. The dielectric fill 280 may include one or more layers of dielectric materials (a combination of one or more of silicon dioxide, silicon nitride, and/or another suitable dielectric material, among other examples).

Although FIGS. 1 and 2 describe the memory system 110 and the bond interface 210 in the context of the die 160 being a NAND die and the die 205 being a logic die, the memory system 110 and/or the bond interface 210 may include different types of die. As a first example, the die 160 may be a NAND array die and the die 205 may be a complementary metal oxide semiconductor (CMOS) die. In this first example, the die 160 and the die 205 may be bonded using the bond interface 210 to form a CMOS-bonded-array (CBA) three dimensional (3D) NAND device. As a second example, the die 160 may be a DRAM array die, and the die 205 may be a CMOS die. In this second example, the die 160 and the die 205 may be bonded using the bond interface 210 to form a CMOS-bonded array (CBA) 3D DRAM device.

FIG. 3 shows example manufacturing flows 300 that support bond pad crack sensor for wafer-to-wafer die stack in accordance with examples as disclosed herein. The manufacturing flows 300 may include operations performed by a combination of one or more semiconductor manufacturing tools at a manufacturing facility such as a semiconductor wafer foundry, an outsourced assembly/test house (OSAT), and/or an original equipment manufacturer (OEM), among other examples.

As shown in FIG. 3, and as part of manufacturing flow 300-a, a sequence of operations may include a bond tool 305 performing a bonding operation, followed by an automated test equipment (ATE) tool 310 performing a testing operation, followed by a wire bond tool 315 performing a wire bonding operation.

For example, and as part of manufacturing flow 300-a, the bond tool 305 (a thermal compression bonding tool, a eutectic bonding tool, a fusion bonding tool, or another suitable bonding tool, among other examples) may be used to perform a bonding operation a stacked die assembly (e.g., the integrated assembly 200 including the die 160 bonded with the die 205) including a bond interface (e.g., the bond interface 210). As part of forming the stacked die assembly, the bond tool 305 may bond a first semiconductor wafer including a first die (e.g., a NAND semiconductor wafer including the die 160) with a second semiconductor wafer including a second die (e.g., a logic semiconductor wafer including the die 205). Alternatively, and in contrast to bonding the first semiconductor wafer with the second semiconductor wafer, the bond tool 305 may be used to bond individual die in discrete form (e.g., bond the die 160 that has been diced or removed from a NAND semiconductor wafer with the die 205 that has been diced/removed from a logic semiconductor wafer).

Furthermore, and as part of manufacturing flow 300-a, the ATE tool 310 (a wafer probe tool or another suitable testing tool, among other examples) may be used to perform a testing operation that tests for cracking and/or defects in a wire bond pad (e.g., the wire bond pad 255) included in the stacked die assembly. The testing operation may include, for example, the ATE tool 310 receiving the stacked die assembly and providing a voltage to the wire bond pad via a probe needle. Using a test circuit (e.g., the crack-sensing circuit 270), the ATE tool 310 may detect an open electrical condition that is indicative of cracking and/or defects in the wire bond pad. In some examples, using the test circuit may include using a comparator.

Furthermore, and as part of manufacturing flow 300-a, the wire bond tool 315 (an ultrasonic wire bonder, a thermosonic wire bonder, a thermocompression wire bonder, or another suitable wire bonder tool, among other examples) may be used perform a wire bonding operation that electrically couples the stacked die assembly with a substrate of a semiconductor package. The wire bonding operation may include, for example, the wire bond tool 315 receiving the stacked die assembly and forming a wire bond to electrically couple the wire bond pad with the substrate. In some examples, the wire bonding operation may be performed after the stacked die assembly is removed (e.g., diced) from the first semiconductor wafer that is joined with the second semiconductor wafer. Additionally, or alternatively, and in some examples, the wire bonding operation may be performed after determining that an open electrical condition does not exist (e.g., after testing the stacked die assembly using the ATE tool 310).

As further shown in FIG. 3, and as part of manufacturing flow 300-b, a sequence of operations may include the ATE tool 310 performing a testing operation, followed by the bond tool 305 performing a bonding operation, followed by the wire bond tool 315 performing a wire bonding operation.

For example, and as part of manufacturing flow 300-b, the ATE tool 310 (a semiconductor wafer probe tool or another suitable testing tool, among other examples) may be used to perform a testing operation that tests for cracking and/or defects in a wire bond pad (e.g., the wire bond pad 255) included in a first die (e.g., the die 160). The operation may include, for example, the ATE tool 310 receiving a first semiconductor wafer (e.g., a NAND semiconductor wafer) including the first die, providing a voltage to the wire bond pad, and using a test circuit (e.g., the crack-sensing circuit 270) to detect an open electrical condition that is indicative of cracking and/or defects in the wire bond pad. In some examples, using the test circuit may include using a comparator. Additionally, or alternatively, the testing operation may include the ATE tool receiving and testing the first die in discrete form (e.g., receiving and testing the die 160 after the die 160 has been diced/removed from a NAND semiconductor wafer).

Furthermore, and part of manufacturing flow 300-b, the bond tool 305 may be used to perform a bonding operation that forms a stacked die assembly (e.g., the integrated assembly 200 including the die 160 and the die 205) including a bond interface (e.g., the bond interface 210). As part of forming the stacked die assembly, the bond tool 305 may bond the first semiconductor wafer including the first die with a second semiconductor wafer including a second die (e.g., a logic semiconductor wafer including the die 205). Alternatively, and in contrast to bonding the first semiconductor wafer with the second semiconductor wafer, the bond tool 305 may be used to bond individual die in discrete form (e.g., bond the die 160 that has been diced or removed from a NAND semiconductor wafer with the die 205 that has been diced/removed from a logic semiconductor wafer). Additionally, or alternatively, and in some examples, the bonding operation may be performed after determining that an open electrical condition does not exist (e.g., after testing the first die using the ATE tool 310).

Furthermore, and as part of manufacturing flow 300-b, the wire bond tool 315 may be used to perform a wire bonding operation that electrically couples the stacked die assembly with a substrate of a semiconductor package. As part of electrically coupling the stacked die assembly with the substrate, the wire bond tool may form a wire bond that electrically couples the wire bond pad with the substrate. In some examples, the wire bonding operation may be performed after the stacked die assembly is removed (e.g., diced) from the first semiconductor wafer that is bonded with the second semiconductor wafer.

As further shown in FIG. 3, and as part of manufacturing flow 300-c, a sequence of operations may include the bond tool 305 performing a bonding operation, followed by the wire bond tool 315 performing a wire bonding operation, followed by the ATE tool 310 performing a testing operation.

As of manufacturing flow 300-c, the bond tool 305 may be used to perform a bonding operation that forms a stacked die assembly (e.g., the integrated assembly 200 including the die 160 and the die 205) including a bond interface (e.g., the bond interface 210). As part of forming the stacked die assembly, the bond tool 305 may bond the first semiconductor wafer including the first die with a second semiconductor wafer including a second die (e.g., a logic semiconductor wafer including the die 205). Alternatively, and in contrast to bonding the first semiconductor wafer with the second semiconductor wafer, the bond tool 305 may be used to bond individual die in discrete form (e.g., bond the die 160 that has been diced or removed from a NAND semiconductor wafer with the die 205 that has been diced/removed from a logic semiconductor wafer).

Furthermore, and as part of manufacturing flow 300-c, the wire bond tool 315 may be used to perform a wire bonding operation that electrically couples the stacked die assembly with a substrate of a semiconductor package. As part of electrically coupling the stacked die assembly with the substrate, the wire bond tool may form a wire bond that electrically couples the wire bond pad with the substrate.

Furthermore, and as part of manufacturing flow 300-c, the ATE tool 310 (an open/shorts tester, a package tester, or another suitable testing tool, among other examples) may be used to perform a testing operation that tests for cracking and/or defects in a wire bond pad (e.g., the wire bond pad 255) included in a first die (e.g., the die 160). The operation may include, for example, the ATE tool 310 receiving the stacked die assembly including the first die after the stacked die assembly is electrically coupled (e.g., wire bonded) with a substrate, providing a voltage to the wire bond pad, and using a test circuit (e.g., the crack-sensing circuit 270) to detect an open electrical condition that is indicative of cracking and/or defects in the wire bond pad. In some examples, using the test circuit may include using a comparator.

Manufacturing flow 300-a is an example of a manufacturing flow that accommodates testing of a wire bond pad (e.g., the wire bond pad 255) after formation of a stacked die assembly (e.g., the integrated assembly 200). In contrast, manufacturing flow 300-b is an example of a manufacturing flow that accommodates testing of the wire bond pad prior to formation of the stacked die assembly. Furthermore, manufacturing flow 300-c is an example of a manufacturing flow that accommodates testing of the wire bond pad after electrically coupling the wire bond pad with a substrate. Implementation of manufacturing flow 300-a, manufacturing flow 300-b, or manufacturing flow 300-c may be dependent on factors that include a maturity of a process (e.g., a maturity of process nodes use to fabricate the die 160 and/or the die 205), a maturity of an operation (e.g., a wafer and/or a die bonding operation used to bond the die 160 with the die 205), and/or yield considerations (e.g., an effective yield of the integrated assembly 200 or a system including integrated assembly 200), among other examples.

FIG. 4 shows a flowchart illustrating a method 400 that supports a bond pad crack sensor for a wafer-to-wafer die stack in accordance with examples as disclosed herein. The operations of method 400 may be implemented by one or more semiconductor manufacturing tools or components thereof as described herein. For example, the operations of method 400 may be performed by one or more semiconductor manufacturing tools at a semiconductor manufacturing facility (e.g., a semiconductor wafer foundry, an OSAT, or an OEM). In some examples, a semiconductor manufacturing tool may execute a set of instructions to control the functional elements of the device to perform the described functions. Additionally, or alternatively, a semiconductor manufacturing tool may perform aspects of the described functions using special-purpose hardware.

At 405, the method may include receiving a memory die including a wire bond pad along a first surface of the memory die and a wafer bond pad along a second surface of the memory die, the second surface opposite the first surface. In some examples, aspects of the operations of 405 may be performed by an ATE tool (e.g., the ATE tool 310) as described with reference to FIG. 3.

At 410, the method may include testing the wire bond pad for cracking defects using a test circuit that is coupled with the wire bond pad via a tungsten layer proximate the first surface. In some examples, one or more aspects of operations at 410 may be performed by the ATE tool as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a memory die including a wire bond pad along a first surface of the memory die and a wafer bond pad along a second surface of the memory die, the second surface opposite the first surface and testing the wire bond pad for cracking defects using a test circuit that is coupled with the wire bond pad via a tungsten layer proximate the first surface.

Aspect 2: The method, apparatus, or non-transitory computer-readable medium of aspect 1, further including operations, features, circuitry, logic, means, or instructions, or any combination thereof for coupling the memory die with another semiconductor die prior to testing the wire bond pad for cracking defects.

Aspect 3: The method, apparatus, or non-transitory computer-readable medium of aspect 2, where the wafer bond pad is a first wafer bond pad, and coupling the memory die with another semiconductor die includes operations, features, circuitry, logic, means, or instructions, or any combination thereof for performing a wafer-to-wafer bonding operation that couples the first wafer bond pad with a second wafer bond pad of a logic die.

Aspect 4: The method, apparatus, or non-transitory computer-readable medium of any of aspects 1 through 3, further including operations, features, circuitry, logic, means, or instructions, or any combination thereof for coupling the memory die with another semiconductor die after testing the wire bond pad for cracking defects.

Aspect 5: The method, apparatus, or non-transitory computer-readable medium of aspect 4, where the wafer bond pad is a first wafer bond pad, and coupling the memory die with another semiconductor die includes operations, features, circuitry, logic, means, or instructions, or any combination thereof for performing a wafer-to-wafer bonding operation that couples the first wafer bond pad with a second wafer bond pad of a logic die.

Aspect 6: The method, apparatus, or non-transitory computer-readable medium of any of aspects 1 through 5, where testing the wire bond pad for cracking defects using the test circuit includes operations, features, circuitry, logic, means, or instructions, or any combination thereof for providing a voltage to the test circuit through the wire bond pad.

Aspect 7: The method, apparatus, or non-transitory computer-readable medium of any of aspects 1 through 6, where testing the wire bond pad for cracking defects using the test circuit includes operations, features, circuitry, logic, means, or instructions, or any combination thereof for determining whether an electrical open condition exists using a comparator.

Aspect 8: The method, apparatus, or non-transitory computer-readable medium of aspect 7, further including operations, features, circuitry, logic, means, or instructions, or any combination thereof for in response to determining that an electrical open condition does not exist, performing a wire bond operation that connects a wire with the wire bond pad.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An integrated assembly, including: a logic die; and a memory die coupled with the logic die at a wafer-to-wafer bond interface, the memory die including: a wafer bond pad along the wafer-to-wafer bond interface; a metallization stack including a base metal layer that, relative to other metal layers of the metallization stack, is nearest the wafer bond pad; a wire bond pad positioned on a surface of the memory die opposite the wafer-to-wafer bond interface; a metallization layer coupled with the wire bond pad, the metallization layer including one or more conductive paths that couple the wafer bond pad with a crack-sensing circuit; and a set of contacts that couple the wire bond pad with the base metal layer.

Aspect 10: The integrated assembly of aspect 9, where the memory die further includes NAND memory cells.

Aspect 11: The integrated assembly of any of aspects 9 through 10, where the metallization layer includes: a contact structure that is included in the set of contacts.

Aspect 12: The integrated assembly of any of aspects 9 through 11, where the base metal layer and the metallization layer each include: tungsten.

Aspect 13: The integrated assembly of any of aspects 9 through 12, where the base metal layer includes bit line structures.

Aspect 14: The integrated assembly of any of aspects 9 through 13, where the wafer-to-wafer bond interface includes: at least one eutectic bond.

Aspect 15: The integrated assembly of any of aspects 9 through 14, where the wafer-to-wafer bond interface includes: hybrid bonds.

An apparatus is described. The following provides an overview of aspects of the apparatus as described herein:

Aspect 16: A memory die, including: a first pad along a first surface of the memory die; a first metallization layer coupled with the first pad; a test circuit coupled with the first pad via the first metallization layer; a second pad along a second surface of the memory die, the second surface opposite the first surface; a second metallization layer coupled with the second pad; and a contact that couples the first metallization layer with the second metallization layer.

Aspect 17: The memory die of aspect 16, where the first pad is configured to provide an electrically conductive bond between the memory die and an electrical connector.

Aspect 18: The memory die of any of aspects 16 through 17, where the second pad is configured to provide an electrical connection between the memory die and another semiconductor die.

Aspect 19: The memory die of any of aspects 16 through 18, where the second pad is configured to provide a mechanical connection between the memory die and another semiconductor die.

Aspect 20: The memory die of any of aspects 16 through 19, where the test circuit includes a comparator configured to detect an electrical open caused by a discontinuity in an electrical path that includes the first pad.

Aspect 21: The memory die of any of aspects 16 through 20, where the contact is a first contact and the first metallization layer is a metallization layer including: a second contact that connects the first pad with the first contact.

Aspect 22: The memory die of any of aspects 16 through 21, where the first metallization layer includes: at least one routing structure that connects the test circuit with the first pad.

Aspect 23: The memory die of any of aspects 16 through 22, where the first surface is configured as a wafer-to-wafer bonding interface for coupling the memory die with another semiconductor die.

Aspect 24: The memory die of any of aspects 16 through 23, where the memory die further includes: two or more stacked levels of NAND memory cells between the first metallization layer and the second metallization layer.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An integrated assembly, comprising:
a logic die; and
a memory die coupled with the logic die at a wafer-to-wafer bond interface, the memory die comprising:
a wafer bond pad along the wafer-to-wafer bond interface;
a metallization stack including a base metal layer that, relative to other metal layers of the metallization stack, is nearest the wafer bond pad;
a wire bond pad positioned on a surface of the memory die opposite the wafer-to-wafer bond interface;
a metallization layer coupled with the wire bond pad, the metallization layer comprising one or more conductive paths that couple the wafer bond pad with a crack-sensing circuit; and
a set of contacts that couple the wire bond pad with the base metal layer.

2. The integrated assembly of claim 1, wherein the memory die further comprises NAND memory cells.

3. The integrated assembly of claim 1, wherein the metallization layer comprises:
a contact structure that is included in the set of contacts.

4. The integrated assembly of claim 1, wherein the base metal layer and the metallization layer each comprise:
tungsten.

5. The integrated assembly of claim 1, wherein the base metal layer includes bit line structures.

6. The integrated assembly of claim 1, wherein the wafer-to-wafer bond interface comprises:
a eutectic bond interface.

7. The integrated assembly of claim 1, wherein the wafer-to-wafer bond interface comprises:
a hybrid bond interface.

8. A memory die, comprising:
a first pad along a first surface of the memory die;
a first metallization layer coupled with the first pad;
a test circuit coupled with the first pad via the first metallization layer;
a second pad along a second surface of the memory die, the second surface opposite the first surface;
a second metallization layer coupled with the second pad; and
a contact that couples the first metallization layer with the second metallization layer.

9. The memory die of claim 8, wherein the first pad is configured to provide an electrically conductive bond between the memory die and an electrical connector.

10. The memory die of claim 8, wherein the second pad is configured to provide an electrical connection between the memory die and another semiconductor die.

11. The memory die of claim 8, wherein the second pad is configured to provide a mechanical connection between the memory die and another semiconductor die.

12. The memory die of claim 8, wherein the test circuit comprises a comparator configured to detect an electrical open caused by a discontinuity in an electrical path that includes the first pad.

13. The memory die of claim 8, wherein the contact is a first contact and the first metallization layer is a metallization layer comprising:
a second contact that connects the first pad with the first contact.

14. The memory die of claim 8, wherein the first metallization layer comprises:
at least one routing structure that connects the test circuit with the first pad.

15. The memory die of claim 8, wherein the first surface is configured as a wafer-to-wafer bonding interface for coupling the memory die with another semiconductor die.

16. The memory die of claim 8, wherein the memory die further comprises:
two or more stacked levels of NAND memory cells between the first metallization layer and the second metallization layer.

17. A method, comprising:
receiving a memory die comprising a wire bond pad along a first surface of the memory die and a wafer bond pad along a second surface of the memory die, the second surface opposite the first surface; and
testing the wire bond pad for cracking defects using a test circuit that is coupled with the wire bond pad via a tungsten layer proximate the first surface.

18. The method of claim 17, further comprising:
coupling the memory die with another semiconductor die prior to testing the wire bond pad for cracking defects.

19. The method of claim 18, wherein the wafer bond pad is a first wafer bond pad and coupling the memory die with another semiconductor die comprises:
performing a wafer-to-wafer bonding operation that couples the first wafer bond pad with a second wafer bond pad of a logic die.

20. The method of claim 17, further comprising:
coupling the memory die with another semiconductor die after testing the wire bond pad for cracking defects.

21. The method of claim 20, wherein the wafer bond pad is a first wafer bond pad and coupling the memory die with another semiconductor die comprises:
performing a wafer-to-wafer bonding operation that couples the first wafer bond pad with a second wafer bond pad of a logic die.

22. The method of claim 17, wherein testing the wire bond pad for cracking defects using the test circuit comprises:
providing a voltage to the test circuit through the wire bond pad.

23. The method of claim 17, wherein testing the wire bond pad for cracking defects using the test circuit comprises:
determining whether an electrical open condition exists using a comparator.

24. The method of claim 23, further comprising:
in response to determining that an electrical open condition does not exist, performing a wire bond operation that connects a wire with the wire bond pad.
